(19) United States
(12) Patent Application Publication
(10) Pub. No.: US 2010/0246131 A1
(43) Pub. Date: Sep. 30, 2010

(54) HEAT SINK AND MOTHERBOARD ASSEMBLY UTILIZING THE HEAT SINK

(75) Inventor: ZHENG-HENG SUN, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/479,692

(22) Filed: Jun. 5, 2009

(30) Foreign Application Priority Data
Mar. 30, 2009 (CN) 200910301219.4

(51) Int. Cl. H05K 7/20

(52) U.S. Cl. 361/704

(57) ABSTRACT

A heat sink for dissipating heat for a motherboard, includes a package portion, a heat dissipating device made of heat conducting material, and a number of grounding pins made of heat conducting material. The package portion includes a top wall. The heat dissipating device is exposed out of the top wall of the package portion. The number of grounding pins extending down through the package portion, to be soldered to a number of bonding grounding pads of a corresponding idle chip installing area of the motherboard, respectively. Top portions of the grounding pins contact the heat dissipating device. A motherboard assembly utilizing the heat sink is also disclosed.

### CROSS-REFERENCE TO RELATED APPLICATION

The present application is related to a co-pending U.S. patent application (Attorney Docket No. US24163) filed on the same date and having the same title with the present application, which is assigned to the same assignee with this patent application.

### BACKGROUND

1. Technical Field

The present disclosure relates to a heat sink and a motherboard assembly utilizing the heat sink.

2. Description of Related Art

An electronic device, such as a computer, usually includes a fan and a heat sink installed on a heat generating component of a motherboard for dissipating heat. However, some of the heat produced by the heat generating component will be transferred to the motherboard through pins of the heat generating component, which will lead to undesirable increase of the temperature of the motherboard.

### BRIEF DESCRIPTION OF THE DRAWINGS

FIG. 1 is an exploded, isometric view of an embodiment of a heat sink together with a motherboard, the heat sink including a heat dissipating device, a plurality of grounding pins and a plurality of supporting pins.

FIG. 2 is an isometric view of the heat dissipating device and the plurality of grounding pins of FIG. 1.

FIG. 3 is an assembled, isometric view of FIG. 1.

### DETAILED DESCRIPTION

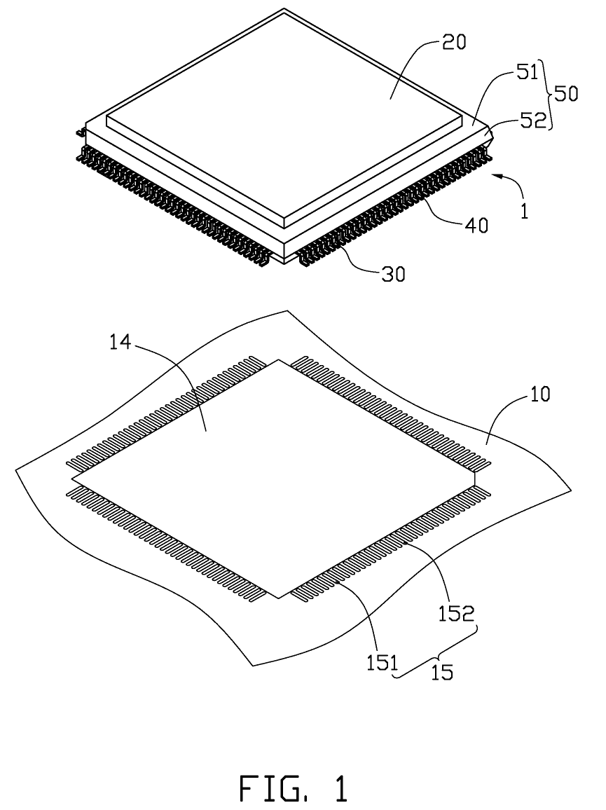

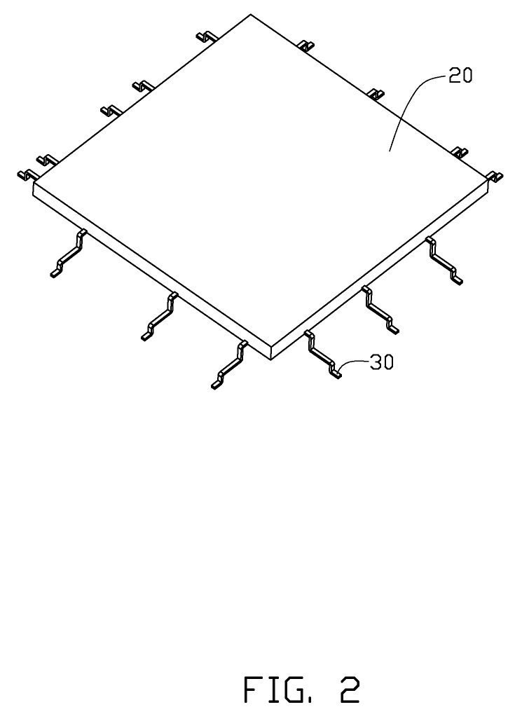

Referring to FIGS. 1 and 2, an embodiment of a heat sink 1 for dissipating heat for a motherboard 10, includes a heat dissipating device 20, a plurality of grounding pins 30, a plurality of supporting pins 40, and a package portion 50 made of insulating material. The package portion 50 includes a top wall 51, and four sidewalls 52 perpendicularly connected to the top wall 51.

The motherboard 10 includes an idle chip installing area 14. The idle chip installing area 14 includes a plurality of bonding pads 15. Some of the bonding pads 15 are bonding grounding pads 151 connected to a grounding layer of the motherboard 10, and the others of the bonding pads 15 are bonding non-grounding pads 152.

The heat dissipating device 20 and the plurality of grounding pins 30 are made of heat conducting material. The plurality of grounding pins 30 are integrally formed from the heat dissipating device 20, corresponding to the bonding grounding pads 151 of the idle chip installing area 14 of the motherboard 10. The heat dissipating device 20, the plurality of grounding pins 30, the plurality of supporting pins 40, and the package portion 50 are packaged to form the heat sink 1. After packaging, the heat dissipating device 20 is exposed out of the top wall 51 of the package portion 50; the plurality of grounding pins 30 and the plurality of supporting pins 40 are exposed out of and extending down from the sidewalls 52 of the package portion 50, corresponding to the bonding grounding pads 151 and the bonding non-grounding pads 152, respectively. The plurality of supporting pins 40 do not contact the heat dissipating device 20. A shape of the heat sink 1 is the same as that of a chip which can be otherwise installed on the idle chip installing area 14 of the motherboard 10; structures and arrangements of the plurality of grounding pins 30 and the plurality of supporting pins 40 are the same as those of the grounding pins and non-grounding pins of the corresponding chip.

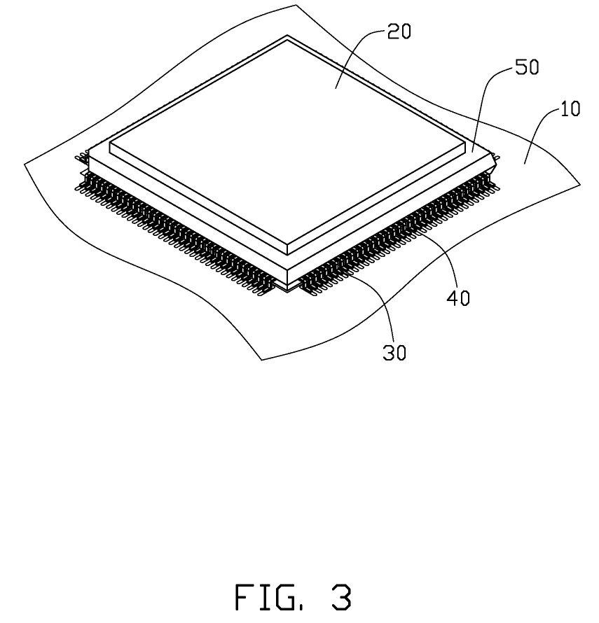

Referring to FIG. 3, in use, the heat sink 1 is placed on the idle chip installing area 14 of the motherboard 10 to allow the plurality of grounding pins 30 and the plurality of supporting pins 40 to contact the bonding grounding pads 151 and the bonding non-grounding pads 152 of the idle chip installing area 14, respectively. The plurality of grounding pins 30 and the plurality of supporting pins 40 are soldered to the bonding grounding pads 151 and the bonding non-grounding pads 152, respectively. Thereby, the heat sink 1 is mounted on the idle chip installing area 14 of the motherboard 10. Heat from the motherboard 90 is transferred to the heat dissipating device 20 through the grounding pins 30, and then is dissipated to the air through the heat dissipating device 20. Therefore, temperature of the motherboard 10 can be kept low. Because the heat sink 1 is mounted on the idle chip installing area 14 of the motherboard 10, which means the heat sink 1 does not occupy other space of the motherboard 10, the heat sink 1 will not influence installation of other electronic components.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A heat sink for dissipating heat for a motherboard, the heat sink comprising:
a package portion comprising a top wall;
a heat dissipating device made of heat conducting material, the heat dissipating device being exposed out of the top wall of the package portion; and
a plurality of grounding pins made of heat conducting material, the plurality of grounding pins extending down through the package portion, to be soldered to a plurality of bonding grounding pads of a corresponding chip installing area of the motherboard, wherein top portions of the plurality of grounding pins contact the heat dissipating device.

2. The heat sink of claim 1, wherein the plurality of grounding pins are integrally formed from the heat dissipating device.

3. The heat sink of claim 1, wherein the package portion is made of insulating material.

4. The heat sink of claim 1, further comprising a plurality of supporting pins, wherein the plurality of supporting pins extend down through the package portion, to be supported on a plurality of bonding non-grounding pads of the corresponding chip installing area of the motherboard.

5. The heat sink of claim 4, wherein the plurality of supporting pins do not contact the heat dissipating device.

6. The heat sink of claim 4, wherein the package portion further comprises four sidewalls connected to the top wall, the plurality of grounding pins and the plurality of supporting pins extend down from the sidewalls of the package portion.

7. A motherboard assembly comprising:
a motherboard comprising an idle chip installing area, the idle chip installing area comprising a plurality of bonding grounding pads; and
a heat sink comprising a package portion, a heat dissipating device exposed out of a top of the package portion, and a plurality of grounding pins contacting the heat dissipating device and extending down through the package portion, wherein the heat dissipating device and the plurality of grounding pins are made of heat conducting material, the plurality of grounding pins are soldered to the plurality of bonding grounding pads, respectively.

8. The motherboard assembly of claim 7, wherein the plurality of grounding pins are integrally formed from the heat dissipating device.

9. The motherboard assembly of claim 7, wherein the package portion is made of insulating material.

10. The motherboard assembly of claim 7, wherein the idle chip installing area further comprises a plurality of bonding non-grounding pads, the heat sink further comprises a plurality of supporting pins extending down through the package portion and supported on the plurality of bonding non-grounding pads, respectively, the plurality of supporting pins do not contact the heat dissipating device.

11. The motherboard assembly of claim 10, wherein the package portion further comprises four sidewalls connected to the top wall, the plurality of supporting pins extend down from the sidewalls of the package portion.

12. The motherboard assembly of claim 10, wherein a shape of the heat sink is the same as that of a chip which can be installed on the idle chip installing area of the motherboard; structures and arrangements of the grounding pins and the supporting pins extending down from the package portion are the same as those of grounding pins and non-grounding pins of the corresponding chip.
